(19) United States
(12) Patent Application Publication
(10) Pub. No.: US 2011/0241228 A1
(43) Pub. Date: Oct. 6, 2011

(54) EPOXY RESIN COMPOSITION FOR SEALING PACKING OF SEMICONDUCTOR, SEMICONDUCTOR DEVICE, AND MANUFACTURING METHOD THEREOF

(75) Inventors: Tetsuya ENOMOTO, Tsukuba-shi (JP); Emi Miyazawa, Tsukuba-shi (JP); Kazutaka Honda, Tsukuba-shi (JP); Akira Nagai, Tsukuba-shi (JP); Keisuke Ookubo, Tsukuba-shi (JP)

(73) Assignee: HITACHI CHEMICAL COMPANY, LTD.

(21) Appl. No.: 13/040,034

(22) Filed: Mar. 3, 2011

(30) Foreign Application Priority Data
Mar. 16, 2010 (JP) P2010-059462

(51) Int. Cl. H01L 23/29; H01L 21/56; C08L 63/00

(52) U.S. Cl. 257/793; 438/127; 523/400; 257/E21.503; 257/E23.119

(57) ABSTRACT

An epoxy resin composition for a underfilling of a semiconductor comprising an epoxy resin, an acid anhydride, a curing accelerator and a flux agent as essential components, wherein the curing accelerator is a quaternary phosphonium salt, as well as a semiconductor device and manufacturing method employing the same.

### BACKGROUND OF THE INVENTION

1. Field of the Invention

The present invention relates to an epoxy resin composition for an underfilling of a semiconductor, to a semiconductor device, and to a method for manufacturing the same.

2. Related Background Art

With ongoing trends toward smaller and higher performance electronic devices in recent years, semiconductor devices that are smaller, thinner and have improved electrical characteristics (such as applicability for high-frequency transmission) are in demand. A simultaneous shift has begun from systems in which semiconductor chips are mounted on boards by conventional wire bonding, to flip-chip connection systems in which conductive protruding electrodes known as a “bumps” are formed on semiconductor chips for direct connection with board electrodes.

The bumps formed on semiconductor chips include bumps composed of solder or gold, but recent years have seen increasing use of bumps that have structures with solder formed on the tips of copper bumps, for suitability to formation of microconnections.

Connections using metal joints are also desired in order to achieve higher reliability, and such methods are being employed not only with C4 joints using solder bumps, or solder joints formed by bumps having structures with solder formed on the tips of copper bumps, but also when using gold bumps, by formation of solder on the board electrode side and creating gold-solder joints.

In flip-chip connection systems as well, since thermal stress created by the difference in thermal expansion coefficients of the semiconductor chips and board can potentially be concentrated at the joints and damage the joints, it is necessary to underfill the gap between the semiconductor chips and board with a resin, in order to disperse the thermal stress and increase the connection reliability. Generally speaking, resin underfilling is accomplished using a system in which the semiconductor chips and board are connected with solder or the like, and then the liquid sealing resin is injected into the gap by capillary flow.

For connection between chips and board, it is common to use flux composed of a rosin or organic acid, to allow removal of the oxide layer on the solder surface by reductive reaction to facilitate metal melting. If flux residue remains in such cases, it can cause generation of air bubbles known as voids when the liquid sealing resin is injected, or corrosion of wiring can occur due to the acid component, thus lowering the connection reliability, and therefore a step of residue cleaning has been required. However, it is often difficult to accomplish cleaning of flux residue because of the narrower gap between the semiconductor chips and board when the connection pitch becomes smaller. In addition, productivity may be reduced because it takes a longer time to inject the liquid sealing resin into the narrower gap between the semiconductor chips and board.

In order to overcome these problems with the liquid sealing resin, there have been proposed connecting methods known as “pre-applied systems” in which a sealing resin having a property allowing removal of the solder surface oxide layer by reductive reaction (flux ability) is applied to the board, and then the gap between the semiconductor chips and board are underfilled with the resin as the semiconductor chips and board are connected, thus allowing cleaning of the flux residue to be skipped, and sealing resins suitable for such “pre-applied systems” have also been proposed (see Patent documents 1-4, for example).

### PRIOR ART DOCUMENTS

### Patent Documents

[Patent document 1] Japanese Unexamined Patent Application Publication No. 2007-107006
[Patent document 2] Japanese Unexamined Patent Application Publication No. 2007-284471
[Patent document 3] Japanese Unexamined Patent Application Publication No. 2007-326941
[Patent document 4] Japanese Unexamined Patent Application Publication No. 2009-203292

### SUMMARY OF THE INVENTION

In pre-applied systems, however, the sealing resin is exposed to high-temperature connecting conditions during solder joint formation, and consequently voids are generated and the connection reliability is reduced.

Furthermore, following solder joint formation under high-temperature connecting conditions, the joints must be reinforced by promoting curing reaction of the sealing resin during the solder joint formation, in order to avoid formation of cracks and the like at the joints during the process of cooling to room temperature, these being caused because thermal stress, which is generated by the difference in the thermal expansion coefficients of the semiconductor chip and board, is concentrated at the joints. However, when the reactivity of the sealing resin is increased, the sealing resin may cure before solder joint formation, causing joint defects, or the storage stability of the sealing resin may be lowered.

It is therefore an object of the present invention to provide an epoxy resin composition for an underfilling of a semiconductor, that has excellent storage stability, adequately inhibits formation of voids during flip-chip connection and can produce satisfactory connection reliability, as well as a semiconductor device and a manufacturing method employing the same.

The invention provides an epoxy resin composition for an underfilling of a semiconductor (hereunder also referred to simply as “epoxy resin composition”) comprising an epoxy resin, an acid anhydride, a curing accelerator and a flux agent as essential components, wherein the curing accelerator is a quaternary phosphonium salt.

According to the epoxy resin composition for an underfilling of a semiconductor, it is possible to obtain excellent storage stability, adequately prevent formation of voids during flip-chip connection and produce satisfactory connection reliability.

The quaternary phosphonium salt is preferably a tetraalkylphosphonium salt or tetraarylphosphonium salt, from the viewpoint of allowing the storage stability to be further improved.

The epoxy resin composition preferably further comprises an inorganic filler for lower thermal expansion.

The epoxy resin composition is preferably formed into a film, from the viewpoint of improving the workability.

The invention further provides a method for manufacturing a semiconductor device that comprises a first step in which the epoxy resin is applied onto semiconductor chips or a board, and a second step in which the semiconductor chips and board are aligned, and then flip-chip connection is formed between the semiconductor chips and board, while underfilling the gap between the semiconductor chips and board is accomplished with an epoxy resin composition.

The invention still further provides a semiconductor device comprising a board, semiconductor chips electrically connected with the board, and a sealing resin consisting of a cured product of the epoxy resin composition, that seals the gap between the board and semiconductor chips.

The semiconductor device has excellent connection reliability since it employs an epoxy resin composition of the invention.

According to the invention it is possible to provide an epoxy resin composition for an underfilling of a semiconductor, that has excellent storage stability, adequately inhibits formation of voids during flip-chip connection and can produce satisfactory connection reliability, as well as a semiconductor device and a manufacturing method employing the same.

### BRIEF DESCRIPTION OF THE DRAWINGS

FIG. 1 is a schematic cross-sectional view showing an embodiment of a semiconductor device according to the invention.

### DESCRIPTION OF THE EMBODIMENTS

The epoxy resin composition of the invention comprises an epoxy resin, an acid anhydride, a flux agent and a curing accelerator as essential components.

The epoxy resin is not particularly restricted so long as it is bifunctional or greater, and for example, there may be used bisphenol A-type epoxy resins, bisphenol F-type epoxy resins, bisphenol S-type epoxy resins, phenol-novolac-type epoxy resins, cresol-novolac-type epoxy resins, biphenyl-type epoxy resins, hydroquinone-type epoxy resins, diphenyl sulfide skeleton-containing epoxy resins, phenolaralkyl-type polyfunctional epoxy resins, naphthalene skeleton-containing polyfunctional epoxy resins, dicyclopentadiene skeleton-containing polyfunctional epoxy resins, triphenylmethane skeleton-containing polyfunctional epoxy resins, aminophenol-type epoxy resins, diaminodiphenylmethane-type epoxy resins, and various other types of polyfunctional epoxy resins. Preferably used among these, from the viewpoint of viscosity reduction, low water absorption and high heat resistance, are bisphenol A-type epoxy resins, bisphenol F-type epoxy resins, naphthalene skeleton-containing polyfunctional epoxy resins, dicyclopentadiene skeleton-containing polyfunctional epoxy resins and triphenylmethane skeleton-containing polyfunctional epoxy resins: These epoxy resins may be either liquid or solid at 25° C., but when solder is hot melted for connection, a solid epoxy resin used preferably has a melting point or softening point lower than the melting point of the solder. These epoxy resins may also be used alone or in combinations of two or more.

As examples of acid anhydrides there may be mentioned maleic anhydride, succinic anhydride, dodecenylsuccinic anhydride, phthalic anhydride, tetrahydrophthalic anhydride, methyltetrahydrophthalic anhydride, hexahydrophthalic anhydride, methylhexahydrophthalic anhydride, endomethylenetetrahydrophthalic acid, methylendomethylenetetrahydrophthalic acid, methylhymic anhydride, pyromellitic dianhydride, benzophenonetetracarboxylic dianhydride, polyazelaic anhydride, alkylstyrene-maleic anhydride copolymer, 3,4-dimethyl-6-(2-methyl-1-propenyl)-4-cyclohexene-1,2-dicarboxylic anhydride, 1-isopropyl-4-methyl-bicyclo[2.2.2]oct-5-ene-2,3-dicarboxylic anhydride, ethyleneglycol bistrimellitate and glycerol trisanhydrotrimellitate. Particularly preferred among these from the viewpoint of heat resistance and humidity resistance are methyltetrahydrophthalic anhydride, methylhexahydrophthalic anhydride, endomethylenetetrahydrophthalic acid, methylendomethylenetetrahydrophthalic acid, 3,4-dimethyl-6-(2-methyl-1-propenyl)-4-cyclohexene-1,2-dicarboxylic anhydride, 1-isopropyl-4-methyl-bicyclo[2.2.2]oct-5-ene-2,3-dicarboxylic anhydride, ethyleneglycol bistrimellitate and glycerol trisanhydrotrimellitate. Any of these may be used alone or in mixtures of two or more.

The amount of acid anhydride added is preferably 0.5-1.5 and more preferably 0.7-1.2, as the equivalent ratio to the epoxy resin (the ratio of the number of epoxy groups and the number of carboxyl groups generated from the acid anhydride=number of epoxy groups/number of carboxyl groups). If the equivalent ratio is smaller than 0.5, excessive carboxyl groups will remain, the water absorption may be increased and the moisture-proof reliability may be reduced, while if the equivalent ratio is larger than 1.5, the curing may not proceed sufficiently.

The flux agent used is preferably at least one compound selected from among alcohols, phenols and carboxylic acids.

An alcohol is preferably a compound with a two or more alcoholic hydroxyl groups in the molecule. Specific examples include 1,3-dioxane-5,5-dimethanol, 1,5-pentanediol, 2,5-furanedimethanol, diethylene glycol, tetraethylene glycol, pentaethylene glycol, hexaethylene glycol, 1,2,3-hexanetriol, 1,2,4-butanetriol, 1,2,6-hexanetriol, 3-methylpentane-1,3,5-triol, glycerin, trimethylolethane, trimethylolpropane, erythritol, pentaerythritol, ribitol, sorbitol, 2,4-diethyl-1,5-pentanediol, propyleneglycol monomethyl ether, propyleneglycol monoethyl ether, 1,3-butylene glycol, 2-ethyl-1,3-hexanediol, N-butyldiethanolamine, N-ethyldiethanolamine, diethanolamine, triethanolamine, N,N-bis(2-hydroxyethyl)isopropanolamine, bis(2-hydroxymethyl)iminotris(hydroxymethyl)methane, N,N,N′,N′-tetrakis(2-hydroxyethyl)ethylenediamine and 1,1′,1″,1′″-(ethylenedinitrilo)tetrakis(2-propanol). These compounds may be used alone or in combinations of two or more.

A phenol is preferably a compound with at least two phenolic hydroxyl groups. Specific examples include catechol, resorcinol, hydroquinone, biphenol, dihydroxynaphthalene, hydroxyhydroquinone, pyrogallol, methylidenebiphenol (bisphenol F), isopropylidenebiphenol (bisphenol A), ethylidenebiphenol (bisphenol AD), 1,1,1-tris(4-hydroxyphenyl)ethane, trihydroxybenzophenone, trihydroxyacetophenone and poly-p-vinylphenol. As compounds with at least two phenolic hydroxyl groups there may be used polycondensates of one or more compounds selected from among compounds having at least one phenolic hydroxyl group in the molecule, and one or more compounds selected from among aromatic compounds having two halomethyl, alkoxymethyl or hydroxylmethyl groups in the molecule, divinylbenzenes and aldehydes. Examples of compounds having at least one phenolic hydroxyl group in the molecule include phenol, alkylphenols, naphthol, cresol, catechol, resorcinol, hydroquinone, biphenol, dihydroxynaphthalene, hydroxyhydroquinone, pyrogallol, methylidenebiphenol (bisphenol F), isopropylidenebiphenol (bisphenol A), ethylidenebiphenol (bisphenol AD), 1,1,1-tris(4-hydroxyphenyl)ethane, trihydroxybenzophenone, trihydroxyacetophenone and poly-p-vinylphenol. Examples of aromatic compounds having two halomethyl, alkoxymethyl or hydroxylmethyl groups in the molecule include 1,2-bis(chloromethyl)benzene, 1,3-bis(chloromethyl)benzene, 1,4-bis(chloromethyl)benzene, 1,2-bis(methoxymethyl)benzene, 1,3-bis(methoxymethyl)benzene, 1,4-bis(methoxymethyl)benzene, 1,2-bis(hydroxymethyl)benzene, 1,3 -bis(hydroxymethyl)benzene, 1,4-bis(hydroxymethyl)benzene, bis(chloromethyl)biphenyl and bis(methoxymethyl)biphenyl.

Examples of aldehydes include formaldehyde (or formalin in aqueous solution), paraformaldehyde, trioxane and hexamethylenetetramine.

Examples of polycondensates include phenol-novolac resins, which are polycondensates of phenol and formaldehyde, cresol-novolac resins, which are polycondensates of cresol and formaldehyde, naphthol-novolac resins, which are polycondensates of naphthol and formaldehyde, phenolaralkyl resins, which are polycondensates of phenol and 1,4-bis(methoxymethyl)benzene, polycondensates of bisphenol A and formaldehyde, polycondensates of phenol and divinylbenzene and polycondensates of cresol, naphthol and formaldehyde, which polycondensates may be rubber-modified or may have an aminotriazine skeleton or dicyclopentadiene skeleton introduced into the molecular skeleton.

The state of such compounds may be either solid or liquid at room temperature, but is preferably liquid to allow uniform removal of the oxide layer on the metal surface by reductive reaction and to inhibit solder wettability, and for example, compounds with phenolic hydroxyl groups that have been liquefied by allylation include allylated phenol-novolac resins, diallylbisphenol A, diallylbisphenol F and diallylbiphenols. These compounds may be used alone or in combinations of two or more.

Carboxylic acids include aliphatic carboxylic acids and aromatic carboxylic acids, with solids at 25° C. being preferred.

Examples of aliphatic carboxylic acids include malonic acid, methylmalonic acid, dimethylmalonic acid, ethylmalonic acid, allylmalonic acid; 2,2′-thiodiacetic acid, 3,3′-thiodipropionic acid, 2,2′-(ethylenedithio)diacetic acid, 3,3′-dithiodipropionic acid, 2-ethyl-2-hydroxybutyric acid, dithiodiglycolic acid, diglycolic acid, acetylenedicarboxylic acid, maleic acid, malic acid, 2-isopropylmalic acid, tartaric acid, itaconic acid, 1,3-acetonedicarboxylic acid, tricarballylic acid, muconic acid, β-hydromuconic acid, succinic acid, methylsuccinic acid, dimethylsuccinic acid, glutaric acid, α-ketoglutaric acid, 2-methylglutaric acid, 3-methylglutaric acid, 2,2-dimethylglutaric acid, 3,3-dimethylglutaric acid, 2,2-bis(hydroxymethyl)propionic acid, citric acid, adipic acid, 3-tert-butyladipic acid, pimelic acid, phenyloxalic acid, phenylacetic acid, nitrophenylacetic acid, phenoxyacetic acid, nitrophenoxyacetic acid, phenylthioacetic acid, hydroxyphenylacetic acid, dihydroxyphenylacetic acid, mandelic acid, hydroxymandelic acid, dihydroxymandelic acid, 1,2,3,4-butanetetracarboxylic acid, suberic acid, 4,4′-dithiodibutyric acid, cinnamic acid, nitrocinnamic acid, hydroxycinnamic acid, dihydroxycinnamic acid, coumarinic acid, phenylpyruvic acid, hydroxyphenylpyruvic acid, caffeic acid, homophthalic acid, tolylacetic acid, phenoxypropionic acid, hydroxyphenylpropionic acid, benzyloxyacetic acid, phenyllactic acid, tropic acid, 3-(phenylsulfonyl)propionic acid, 3,3-tetramethyleneglutaric acid, 5-oxoazelaic acid, azelaic acid, phenylsuccinic acid, 1,2-phenylenediacetic acid, 1,3-phenylenediacetic acid, 1,4-phenylenediacetic acid, benzylmalonic acid, sebacic acid, dodecanedioic acid, undecanedioic acid, diphenylacetic acid, benzilic acid, dicyclohexylacetic acid, tetradecanedioic acid, 2,2-diphenylpropionic acid, 3,3-diphenylpropionic acid, 4,4-bis(4-hydroxyphenyl)valeric acid, pimaric acid, palustric acid, isopimaric acid, abietic acid, dehydroabietic acid, neoabietic acid and agathic acid. Examples of aromatic carboxylic acids include benzoic acid, 2-hydroxybenzoic acid, 3-hydroxybenzoic acid, 4-hydroxybenzoic acid, 2,3-dihydroxybenzoic acid, 2,4-dihydroxybenzoic acid, 2,5-dihydroxybenzoic acid, 2,6-dihydroxybenzoic acid, 3,4-dihydroxybenzoic acid, 2,3,4-trihydroxybenzoic acid, 2,4,6-trihydroxybenzoic acid, 3,4,5-trihydroxybenzoic acid, 1,2,3-benzenetricarboxylic acid, 1,2,4-benzenetricarboxylic acid, 1,3,5-benzenetricarboxylic acid, 2-[bis(4-hydroxyphenyl)methyl]benzoic acid, 1-naphthoic acid, 2-naphthoic acid, 1-hydroxy-2-naphthoic acid, 2-hydroxy-1-naphthoic acid, 3-hydroxy-2-naphthoic acid, 6-hydroxy-2-naphthoic acid, 1,4-dihydroxy-2-naphthoic acid, 3,5-dihydroxy-2-naphthoic acid, 3,7-dihydroxy-2-naphthoic acid, 2,3-naphthalenedicarboxylic acid, 2,6-naphthalenedicarboxylic acid, 2-phenoxybenzoic acid, biphenyl-4-carboxylic acid, biphenyl-2-carboxylic acid and 2-benzoylbenzoic acid.

Preferred among these, from the viewpoint of storage stability and ready availability, are succinic acid, malic acid, itaconic acid, 2,2-bis(hydroxymethyl)propionic acid, adipic acid, 3,3′-thiodipropionic acid, 3,3′-dithiodipropionic acid, 1,2,3,4-butanetetracarboxylic acid, suberic acid, sebacic acid, phenylsuccinic acid, dodecanedioic acid, diphenylacetic acid, benzilic acid, 4,4-bis(4-hydroxyphenyl)valeric acid, abietic acid, 2,5-dihydroxybenzoic acid, 3,4,5-trihydroxybenzoic acid, 1,2,4-benzenetricarboxylic acid, 1,3,5-benzenetricarboxylic acid and 2-[bis(4-hydroxyphenyl)methyl]benzoic acid. These compounds may be used alone or in combinations of two or more.

The content of such flux agents is preferably 0.1-15 parts by weight, more preferably 0.5-10 parts by weight and even more preferably 1-10 parts by weight, with respect to 100 parts by weight as the total of the epoxy resin and acid anhydride. If the content is less than 0.1 part by weight a sufficient effect of removing the oxide layer on the solder surface may not be exhibited, and if it exceeds 15 parts by weight the carboxyl groups and epoxy resin in the flux agent may react, potentially lowering the storage stability.

The curing accelerator is not particularly restricted so long as it is a quaternary phosphonium salt, and for example, a tetraalkylphosphonium salt such as a tetramethylphosphonium salt, tetraethylphosphonium salt or tetrabutylphosphonium salt, a tetraarylphosphonium salt such as a tetraphenylphosphonium salt, or a triarylphosphine or trialkylphosphine and 1,4-benzoquinone addition product may be used. Examples include tetraphenylphosphonium bromide, tetra(n-butyl)phosphonium bromide, tetra(4-methylphenyl)phosphonium bromide, methyltriphenylphosphonium bromide, ethyltriphenylphosphonium bromide, methoxymethyltriphenylphosphonium chloride, benzyltriphenylphosphonium chloride, tetra(n-butyl)phosphonium tetrafluoroborate, n-hexadodecyltri(n-butyl)phosphonium tetrafluoroborate, tetraphenylphosphonium tetrafluoroborate, tetra(n-butyl)phosphonium tetraphenylborate, tetraphenylphosphonium tetraphenylborate, tetraphenylphosphonium tetra(4-methylphenyl)borate, tetraphenylphosphonium tetra(4-fluorophenyl)borate, tetra(n-butyl)phosphonium benzotriazolate, tetra(n-butyl)phosphonium diethylphosphodithioate, triphenylphosphine and 1,4-benzoquinone addition products, tri(4-methylphenyl)phosphine and 1,4-benzoquinone addition products, tri(n-butyl)phosphine and 1,4-benzoquinone addition products, and tri(cyclohexyl)phosphine and 1,4-benzoquinone addition products. Preferred among these from the viewpoint of impurity ions or storage stability are tetra(n-butyl)phosphonium tetrafluoroborate, n-hexadodecyltri(n-butyl)phosphonium tetrafluoroborate, tetraphenylphosphonium tetrafluoroborate, tetra(n-butyl)phosphonium tetraphenylborate, tetraphenylphosphonium tetraphenylborate, tetraphenylphosphonium tetra(4-methylphenyl)borate and tetraphenylphosphonium tetra(4-fluorophenyl)borate. When using a tertiary amine or imidazole, which are widely used as curing accelerators of acid anhydride, the storage stability is reduced compared to using a quaternary phosphonium salt.

The content of such a quaternary phosphonium salt is preferably 0.01-10 parts by weight and more preferably 0.1-5 parts by weight, with respect to 100 parts by weight as the total of the epoxy resin and acid anhydride. If the content is less than 0.01 part by weight the curability will be reduced, potentially lowering the connection reliability, while if it is greater than 10 parts by weight the storage stability may be reduced.

The gelation time of the epoxy resin composition at 250° C. is preferably 3-30 seconds, more preferably 3-20 seconds and even more preferably 3-15 seconds. At shorter than 3 seconds, curing may occur before the solder has melted, and at longer than 30 seconds the productivity may be reduced or the curing may be insufficient. The gelation time is the time until the epoxy resin composition becomes unstirrable, when it is placed on a hot plate set to 250° C. and stirred with a spatula.

The epoxy resin composition may be a paste or film at room temperature, but from the viewpoint of workability it is preferably a film.

The epoxy resin composition may also comprise a thermoplastic resin for formation into a film. Examples of thermoplastic resins include phenoxy resins, polyimide resins, polyamide resins, polycarbodiimide resins, phenol resins, cyanate ester resins, acrylic resins, polyester resins, polyethylene resins, polyethersulfone resins, polyetherimide resins, polyvinylacetal resins, polyvinyl butyral resins, urethane resins, polyurethaneimide resins and acrylic rubber, among which phenoxy resins, polyimide resins, polyvinyl butyral resins, polyurethaneimide resins and acrylic rubber which have excellent heat resistance and film formability are preferred, and phenoxy resins and polyimide resins are more preferred. The weight-average molecular weight is preferably greater than 5000, even more preferably 10,000 or greater and even more preferably 20,000 or greater, because at lower than 5000 the film formability is sometimes impaired. The weight-average molecular weight is the value measured by GPC (Gel Permeation Chromatography) based on polystyrene. These thermoplastic resins may be used alone or as mixtures or copolymers of two or more different types.

The content of such thermoplastic resins is preferably 5-200 parts by weight, more preferably 15-175 parts by weight and even more preferably 25-150 parts by weight, with respect to 100 parts by weight as the total of the epoxy resin and acid anhydride. At less than 5 parts by weight the film formability may be reduced and the workability may be impaired, and at greater than 200 parts by weight the heat resistance or reliability may be lowered.

The epoxy resin composition may further comprise a filler to adjust the viscosity or control the properties of the cured product. The filler may be either an organic filler or an inorganic filler, but particularly when the composition is to be used as a resin composition for an underfilling of a semiconductor, an inorganic filler is preferred for low thermal expansion design.

Examples of inorganic fillers include glass, silicon dioxide (silica), aluminum oxide (alumina), titanium oxide (titania), magnesium oxide (magnesia), carbon black, mica and barium sulfate. These may be used alone or in combinations of two or more. The inorganic filler may also be a complex oxide comprising two or more metal oxides (not simply a mixture of two or more metal oxides, but a state in which the metal oxides are chemically bonded and are inseparable). Specific examples include complex oxides such as silicon dioxide and titanium oxide, silicon dioxide and aluminum oxide, boron oxide and aluminum oxide and silicon dioxide, aluminum oxide and magnesium oxide.

The filler form is not particularly restricted and may be pulverized, needle-like, flaky or spherical, but from the viewpoint of dispersibility and viscosity control it is preferably spherical. The filler size need only be a mean particle size smaller than the gap between the semiconductor chips and board during flip-chip connection, but form the viewpoint of filling density and viscosity control, it is preferably a mean particle size of no greater than 10 μm, more preferably no greater than 5 μm and most preferably no greater than 3 μm. In order to adjust the viscosity or the physical properties of the cured product, two or more different ones with different particle sizes may be used in combination.

The filler content is preferably no greater than 200 parts by weight and more preferably no greater than 175 parts by weight with respect to 100 parts by weight as the total of the epoxy resin and acid anhydride. A content of greater than 200 parts by weight will tend to increase the viscosity of the resin composition.

The epoxy resin composition may further contain additives, such as a silane coupling agent, titanium coupling agent, antioxidant, leveling agent or ion trapping agent. These may be used alone or in combinations of two or more. Their contents may be adjusted as suitable to exhibit the effects of the additives.

The epoxy resin composition may be used by stirring and mixing the epoxy resin, acid anhydride, flux agent and curing accelerator using a planetary mixer, kneader, bead mill or the like. When a filler is added, a triple roll may be used for kneading to disperse the filler in the resin composition.

The epoxy resin composition may be formed into a film (film-like resin composition) by the method described below, for example. The thermoplastic resin, epoxy resin, acid anhydride, flux agent, curing accelerator, filler and other additives may be mixed in an organic solvent such as toluene, ethyl acetate, methyl ethyl ketone, cyclohexanone or N-methylpyrrolidone using a planetary mixer or bead mill, to prepare a varnish. The obtained varnish may be coated onto a film base such as a release-treated polyethylene terephthalate resin using a knife coater or roll coater, and then the organic solvent removed by drying to obtain a film-like resin composition.

A semiconductor device fabricated using an epoxy resin composition of the invention will now be described.

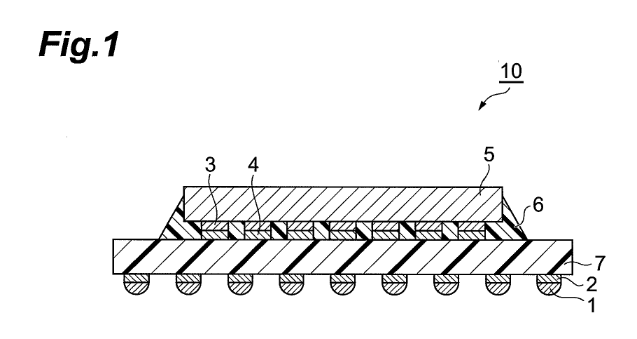

FIG. 1 is a schematic cross-sectional view showing an embodiment of a semiconductor device according to the invention. The semiconductor device 10 shown in FIG. 1 comprises a circuit board 7, a semiconductor chip 5, and a sealing resin 6 situated between the circuit board 7 and semiconductor chip 5. The sealing resin 6 is the cured product of a resin composition for an underfilling of a semiconductor according to the invention, and it seals the gap between the circuit board 7 and semiconductor chip 5. The circuit board 7 comprises a board such as an interposer, and wiring 4 formed on one side of the board. The wiring 4 and semiconductor chip 5 of the circuit board 7 are electrically connected by a plurality of bumps 3. Also, the circuit board 7 has a side on which the wiring 4 is formed, an electrode pad 2 on the opposite side, and a solder ball 1 formed on the electrode pad 2, and it is connectable to another circuit member.

The circuit board 7 may be an ordinary circuit board, or a semiconductor chip. When a circuit board is used, it may be one having a wiring pattern formed thereon by etching removal of the unwanted portions of a metal layer such as copper formed on an insulating substrate surface made of glass epoxy, polyimide, polyester, ceramic or the like, one having a wiring pattern foitned thereon by copper plating on an insulating substrate surface, or one having a wiring pattern formed by printing a conductive substance on an insulating substrate surface. A metal layer made of low melting point solder, high melting point solder, tin, indium, gold, nickel, silver, copper, palladium or the like may also be formed on the surface of the wiring pattern, and the metal layer may be composed of a single component or a plurality of components. A structure with a plurality of laminated metal layers may also be employed.

There are no particular restrictions on the semiconductor chip 5, and various types of semiconductors may be used, including element semiconductors of silicon, germanium or the like or compound semiconductors of gallium-arsenic, indium-phosphorus or the like.

The bumps 3 are conductive protrusions. The material used may be low melting point solder, high melting point solder, tin, indium, gold, silver, copper or the like, and it may be composed of a single material or of a plurality of components. It may also have a structure in which these metals are laminated. Widely used types include solder bumps, copper bumps, bumps having solder formed on copper pillar tips, and gold bumps. The bumps may be formed on the semiconductor chip, or on the board, or on both the semiconductor chip and board.

The semiconductor device of the invention may be one similar to the semiconductor package shown in FIG. 1, wherein a semiconductor chip is mounted on a board known as an interposer and sealed with a resin, and specifically, it may be a CSP (chip-size package) or BGA (ball grid array). A different type of semiconductor package is one wherein the electrode sections of the semiconductor chip are redistributed on the semiconductor chip surface to allow mounting on the board without using an interposer, and “wafer level packages” are such types. The board on which a semiconductor package of the invention is to be mounted will usually be a circuit board, and such a board is referred to as the “motherboard” in relation to the interposer.

One mode of the method for manufacturing a semiconductor device according to the invention is the following, based on an example using a solder bump-formed semiconductor chip.

(1) First Step of Applying Epoxy Resin Composition

When the epoxy resin composition is a paste, a dispenser is used to coat it onto prescribed sections of a semiconductor chip or board. The amount of epoxy resin composition applied is determined, for example, according to the size of the semiconductor chip and the heights of the bumps, and it is appropriately set to an amount that allows the gap between the semiconductor chip and board to be completely filled, without propagation of the resin onto the semiconductor chip side walls during flip-chip connection and attachment to the connecting apparatus. When a film-like resin composition is used, it is attached to the semiconductor chip or board by hot pressing, roll lamination, vacuum lamination or the like. In addition, the film-like resin composition may be attached to a semiconductor chip, or the film-like resin composition may be attached to a semiconductor wafer and then diced for individuation into semiconductor chips, thereby fabricating semiconductor chips with the film-like resin composition attached.

(2) Second Step of Flip-Chip Connection Between Semiconductor Chip and Board

After alignment of the semiconductor chip and board using a connecting apparatus such as a flip-chip bonder, the semiconductor chip and board are pressed together while heating at a temperature at or above the melting point of the solder bumps, so that the semiconductor chip and board are connected while the gap between the semiconductor chip and board is underfilled by the melted epoxy resin composition. The flux agent in the epoxy resin composition of the invention causes removal of the oxide layer on the solder bump surface by reductive reaction, so that the solder bumps are melted smoothly and a joint is formed by metal bonding.

In addition, after the semiconductor chip and board have been aligned and the semiconductor chip and board pressed together at a lower temperature than the melting point of the solder bump for anchoring, they may be heat treated in a reflow furnace to melt the solder bumps and form a joint between the semiconductor chip and board, thereby producing a semiconductor device.

Alternatively, the semiconductor chip and board may be aligned and pressed while heating at a temperature at which the solder bumps do not melt but higher than the active temperature of the flux agent, so that the resin is eliminated between the bumps of the semiconductor chip and the board electrode to underfill the gap between the semiconductor chip and board, while also removing the oxide layer on the solder surface, and then heating is performed again at a temperature above the melting point of the solder to melt the solder bumps and connect the semiconductor chip and board. When heating is performed again at a temperature above the melting point of the solder, a flip-chip bonder may be used, or heat treatment may be carried out in a reflow furnace.

The active temperature of the flux agent is the temperature at which an effect of reducing the oxide layer on the metal surface of solder, tin or the like begins to be exhibited. With a flux agent that is liquid at room temperature, flux ability is exhibited at room temperature or above. With a flux agent that is solid at room temperature, flux ability is exhibited once uniform wetting of the metal surface of solder, tin or the like occurs when it is converted to a liquid or low viscosity state at a temperature at or above its melting point or softening point, and therefore the active temperature is the melting point or softening point.

For increased connection reliability, the semiconductor device obtained in the second step may be heat treated in a heating oven or the like, to further promote curing reaction of the epoxy resin composition.

### EXAMPLES

The invention will now be explained by examples and comparative examples, with the understanding that the scope of the invention is not limited thereby.

### Examples 1-5 and Comparative Examples 1-3

Materials based on the compositions listed in Table 1 were dissolved and mixed to a solid concentration of 50-70% in a toluene-ethyl acetate solvent to prepare varnishes, each of which was coated onto a separator film (PET film) using a knife coater and then dried for 10 minutes in an oven at 70° C. to produce a film-like resin composition with a thickness of 25-30 μm.

TABLE 1

| Starting | | | | | | Comp. | Comp. | Comp. |
|---|---|---|---|---|---|---|---|---|
| material | Example 1 | Example 2 | Example 3 | Example 4 | Example 5 | Ex. 1 | Ex. 2 | Ex. 3 |
| Phenoxy | 45 | 45 | 45 | 45 | 45 | 45 | 45 | 45 |
| resin | | | | | | | | |
| Epoxy resin | 35 | 35 | 35 | 35 | 35 | 35 | 35 | 35 |
| Acid | 20 | 20 | 20 | 20 | 20 | 20 | 20 | 20 |
| anhydride | | | | | | | | |
| Flux agent 1 | 3 | 3 | 3 | 3 | — | 3 | 3 | — |
| Flux agent 2 | — | — | — | — | 5 | — | — | — |
| Curing | 1 | — | — | — | — | — | — | — |
| accelerator 1 | | | | | | | | |
| Curing | | 1 | — | — | — | — | — | — |
| accelerator 2 | | | | | | | | |
| Curing | — | — | 1 | — | — | — | — | — |
| accelerator 3 | | | | | | | | |
| Curing | — | — | — | 1 | 1 | — | — | 1 |
| accelerator 4 | | | | | | | | |
| Curing | — | — | — | — | — | 1 | — | — |
| accelerator 5 | | | | | | | | |
| Curing | — | — | — | — | — | — | 1 | — |
| accelerator 6 | | | | | | | | |
| Filler | 100 | 100 | 100 | 100 | 100 | 100 | 100 | 100 |

(Starting Materials)

Phenoxy resin: ε-Caprolactone-modified phenoxy resin, PKCP80 (product name of Inchem Corporation).

Epoxy resin: Trisphenolmethane-type polyfunctional epoxy resin, EP1032H60 (product name of Japan Epoxy Resins Co., Ltd.).

Acid anhydride: Mixture of 3,4-dimethyl-6-(2-methyl-1-propenyl)-4-cyclohexene-1,2-dicarboxylic anhydride and 1 -isopropyl-4-methylbicyclo-[2.2.2]oct-5 -ene-2,3 -dicarboxylic anhydride, YH307 (product name of Japan Epoxy Resins Co., Ltd.).

Flux agent 1: Adipic acid (product name of Sigma-Aldrich Japan, KK., melting point: 152° C.).

Flux agent 2: Diphenolic acid (product name of Sigma-Aldrich Japan, KK., melting point: 167° C.).

Curing accelerator 1: Tetra(n-butyl)phosphonium tetrafluoroborate, PX-4FB (product name of Nippon Chemical Industrial Co., Ltd.)

Curing accelerator 2: n-Hexadodecyltri(n-butyl)phosphonium tetrafluoroborate, PX-416FB (product name of Nippon Chemical Industrial Co., Ltd.)

Curing accelerator 3: Tetra(n-butyl)phosphonium tetraphenylborate, PX-4PB (product name of Nippon Chemical Industrial Co., Ltd.)

Curing accelerator 4: Tetraphenylphosphonium tetraphenylborate, TPP-K (product name of Hokko Chemical Industry Co., Ltd.).

Curing accelerator 5: Triphenylphosphine, TPP (product name of Hokko Chemical Industry Co., Ltd.).

Curing accelerator 6: 2-Phenyl-4,5-dihydroxymethylimidazole, 2PHZ (product name of Shikoku Chemicals Corp.).

Filler: Spherical silica SE2050 (product name of Admatechs).

[Evaluation of Film-Like Resin Compositions]

The film-like resin compositions obtained in Examples 1-5 and Comparative Examples 1-3 were evaluated in the following manner. The results are shown in Table 2.

(Viscosity Measurement)

The viscosity was measured in the following manner according to formula (1) and formula (2), based on the parallel-plate plastometer method. The film-like resin composition punched into a circular form with a diameter of 6 mm was attached to a 15 mm-square (0.7 mm-thick) glass plate, and after releasing the separator film, an oxide layer-attached silicon chip (size: 12 mm square, thickness: 0.55 mm) was situated with the oxide layer side in contact with the film-like resin composition. This was placed in an FCB3 flip-chip bonder (product name of Panasonic Factory Solutions Co., Ltd.) and thermocompression bonded under conditions with a head temperature of 290° C., a stage temperature of 50° C., a load of 14N and a pressing time of 5 seconds (actual temp. between silicon chip and glass plate reaches at 250° C.). Since the relationship of formula (2) applies if a constant resin volume is assumed, the post-pressing radius was measured with a microscope and the viscosity at 250° C. was calculated according to formula (1).

$$\begin{matrix}[ Formula 1 ] & \\ \begin{matrix}η = \frac{8 π {FtZ}^{4} {Z}_{0}^{4}}{3 {V}^{2} ( {Z}_{0}^{4} - {Z}^{4} )} & \end{matrix} & formula ( 1 )\end{matrix}$$

η: Viscosity (Pa·s)

F: Load (N)

t: Pressing time (s)

Z: Post-pressing resin thickness (m)

Z₀: Pre-pressing resin thickness (m)

V: Resin volume (m³)

Z/Z₀=(r₀/r)² formula (2)

Z₀: Pre-pressing resin thickness

Z: Post-pressing resin thickness

r₀: Pre-pressing resin radius (Punched to 6 mm diameter, hence 3 mm).

r: Post-pressing resin radius

(Storage Stability)

The film-like resin composition was allowed to stand in a thermostatic chamber at 40° C., and samples were evaluated as acceptable (+) if the 250° C. viscosity after 72 hours was no greater than 3 times the initial viscosity, or unacceptable (×) if it was less than 3 times the initial viscosity. The viscosity measurement was conducted by the method described above.

(Measurement of Gelation Time)

The film-like resin composition from which the separator had been released was placed on a hot plate at 250° C., and the time until stirring with a spatula was no longer possible was recorded as the gelation time.

(Connection Between Semiconductor Chip and Board)

A JTEG PHASE11_{—}80 by Hitachi ULSI Systems Co., Ltd. (size: 7.3 mm×7.3 mm, bump pitch: 80 μm, bump count: 328, thickness: 0.55 mm, trade name) was prepared as a semiconductor chip on which were formed bumps each having a structure with a lead-free solder layer (Sn-3.5Ag: melting point=221° C.) on a copper pillar tip, and a glass epoxy board having on the surface a copper wiring pattern with an anti-corrosion layer formed thereon by pre-flux treatment was prepared as a board. Next, the film-like resin composition was cut to 9 mm×9 mm and attached onto region of the board where the semiconductor chip was mounted, under conditions of 80° C./0.5 MPa/5 sec, and the separator film was released. A film-like resin composition-attached board was held by vacuum chucking onto the stage of an FCB3 flip-chip bonder (product name of Panasonic Factory Solutions Co., Ltd.) set to 40° C., and aligned with the semiconductor chip, and then contact bonding was performed for 5 seconds at a load of 25N and a head temperature of 100° C., (actual temp. between chip and board reaches at 90° C.) as a temporary anchoring step for temporary anchoring of the semiconductor chip onto the board. Next, as a first step, the head temperature of the flip-chip bonder was set to 210° C. and contact bonding was performed for 10 seconds at a load of 25N (actual temp. between silicon chip and board reaches at 180° C.). As a second step, the head temperature of the flip-chip bonder was set to 290° C. and contact bonding was performed for 10 seconds at a load of 25N (actual temp. between silicon chip and board reaches at 250° C.), to obtain a semiconductor device in which the semiconductor chip and board were connected.

(Electrical Test)

The semiconductor device in which the semiconductor chip and board were connected was evaluated as either “acceptable” (+) if daisy chain connection of 328 bumps could be confirmed, or “unacceptable” (−) if daisy chain connection could not be confirmed.

(Evaluation of Voids)

The semiconductor device in which the semiconductor chip and board were connected was observed using an ultrasonic inspection device (FineSAT by Hitachi Construction Machinery Co., Ltd.), and was evaluated as either “acceptable” (+) if the area of voids in the chip area was no greater than 1%, or (×) “unacceptable” if it was less than 1%.

(Evaluation of Joint Quality)

The joint part in the semiconductor device in which the semiconductor chip and board were connected was exposed by cross-sectional polishing, and observed using an optical microscope. An evaluation of “acceptable” (+) was assigned if no trapping was seen in the joint part and the solder had sufficiently wetted the wiring, while otherwise an evaluation of “unacceptable” (×) was assigned.

TABLE 2

| Evaluated | | | | | | Comp. | Comp. | Comp. |
|---|---|---|---|---|---|---|---|---|
| property | Example 1 | Example 2 | Example 3 | Example 4 | Example 5 | Ex. 1 | Ex. 2 | Ex. 3 |
| Initial | 14 | 7 | 8 | 11 | 12 | 44 | 30 | 28 |
| viscosity at | | | | | | | | |
| 250° C. (Pa · s) | | | | | | | | |
| Gelation | 8 | 8 | 7 | 5 | 7 | <5 | 6 | 5 |
| time at | | | | | | | | |
| 250° C. (s) | | | | | | | | |
| Storage | + | + | + | + | + | × | × | × |
| stability | | | | | | | | |
| Conduction | + | + | + | + | + | × | + | × |
| test | | | | | | | | |
| Voids | + | + | + | + | + | × | + | + |
| Connection | + | + | + | + | + | × | + | × |
| state | | | | | | | | |

The results in Table 2 show that the storage stability was reduced in Comparative Example 1, which comprised triphenylphosphine as a tertiary phosphorus compound, and Comparative Examples 2 and 3 which comprised imidazoles, whereas Examples 1-5 which comprised quaternary phosphonium salts maintained reactivity equivalent to Comparative Examples 1-3 while allowing satisfactory storage stability to be realized. In addition, Comparative Example 3 which comprised no flux agent did not allow formation of a satisfactory joint by metal bonding, but Examples 1-5 which comprised flux agents had fewer voids and allowed formation of a satisfactory joint by metal bonding.

As explained above, the epoxy resin composition for an underfilling of a semiconductor according to the invention may be used to ensure satisfactory storage stability while allowing formation of joints by metal bonding with minimal voids.

### Explanation of Symbols

1: Solder ball, 2: electrode pad, 3: bump, 4: wiring, 5: semiconductor chip, 6: sealing resin, 7: circuit board, 10: semiconductor device.

What is claimed is:

1. An epoxy resin composition for an underfilling of a semiconductor comprising an epoxy resin, an acid anhydride, a curing accelerator and a flux agent as essential components, wherein the curing accelerator is a quaternary phosphonium salt.

2. An epoxy resin composition for an underfilling of a semiconductor according to claim 1, wherein the quaternary phosphonium salt is a tetraalkylphosphonium salt or tetraarylphosphonium salt.

3. An epoxy resin composition for an underfilling of a semiconductor according to claim 1, which further comprises an inorganic filler.

4. An epoxy resin composition for an underfilling of a semiconductor according to claim 1, which is formed into a film.

5. A method for manufacturing a semiconductor device that comprises a first step in which an epoxy resin composition for an underfilling of a semiconductor according to claim 1 is applied onto a semiconductor chip or board, and a second step in which the semiconductor chip and board are aligned, and then flip-chip connection is formed between the semiconductor chip and board, while underfilling the gap between the semiconductor chip and board is accomplished with the epoxy resin composition for an underfilling of a semiconductor.

6. A semiconductor device comprising a board, a semiconductor chip electrically connected with the board, and a sealing resin consisting of a cured product of the epoxy resin composition for an underfilling of a semiconductor according to claim 1, that seals the gap between the board and semiconductor chip.
